(19) United States
(12) Patent Application Publication
(10) Pub. No.: US 2010/0097164 A1
(43) Pub. Date: Apr. 22, 2010

(54) TUNED CIRCUIT AND DOUBLE TUNED CIRCUIT

(76) Inventor: Keiichiro Sato, Miyagi-Ken (JP)

Correspondence Address: BRINKS HOFER GILSON & LIONE, P.O. BOX 10395, CHICAGO, IL, 60610, US

(21) Appl. No.: 12/574,968

(22) Filed: Oct. 7, 2009

(30) Foreign Application Priority Data
Oct. 21, 2008 (JP) 2008-270878

(51) Int. Cl. H03J 5/24

(52) U.S. Cl. 334/56

(57) ABSTRACT

A double tuned circuit includes: a primary tuning circuit connected to an input terminal; and a secondary tuning circuit connected to an output terminal. The primary tuning circuit has a primary capacitor connected between the input terminal and a ground and a primary inductor connected between the input terminal and the ground and formed of a first coupling line having a spiral shape. The secondary tuning circuit has a secondary capacitor connected between the output terminal and the ground and a secondary inductor connected between the output terminal and the ground and formed of a second coupling line having the same spiral shape as the first coupling line, arranged alternately with the first coupling line, and having an M-coupling with the first coupling line. A length of the first coupling line in the range from a connection point between the first coupling line and the input terminal to a ground point and a length of the second coupling line in the range from a connection point between the second coupling line and the output terminal to the ground point can be changed by a tuning frequency, and the lengths of those are substantially equal to each other.

### CROSS REFERENCE TO RELATED APPLICATION

The present invention contains subject matter related to anc claims priority to Japanese Patent Application No. 2008-270878 filed in the Japanese Patent Office on Oct. 21, 2008, the entire contents of which being incorporated herein by reference.

### BACKGROUND

1. Technical Field

The present disclosure relates to a tuned circuit and a double tuned circuit usable for a television tuner.

2. Related Art

Generally, television tuners are known in which one tuner is used to perform reception by switching a plurality of broadcast signal bands (for example, three bands of VHF-Low, VHF-Hi, and UHF). These television tuners, as shown in FIG. 5, have a circuit configuration of three systems such as a VHF-Low receiving system, a VHF-Hi receiving system, and a UHF receiving system provided in parallel. The VHF-Low receiving system includes a tuned circuit 50a, an amplification circuit (FET: field effect transistor) 51a, and a double tuned circuit 52a. The VHF-Hi receiving system includes a tuned circuit 50b, an amplification circuit 51b, and a double tuned circuit 52b.

The UHF receiving system includes a tuned circuit 50c, an amplification circuit 51c, and a double tuned circuit 52c. As shown in FIG. 6, the tuned circuits 50a, 50b, and 50c are formed of air core coils and varactor diodes. In addition, the double tuned circuits 52a, 52b, and 52c are formed of a primary tuning circuit including the air core coils and the varactor diodes and a secondary tuning circuit including the air core coils and the varactor diodes.

In the low frequency band (VHF-Low), it is difficult to form an M coupling with the air core coils. Hence, the air core coils of the primary tuning circuit and the air core coils of the secondary tuning circuit form an L coupling (a direct coupling). Further, in the high frequency bands (VHF-Hi, UHF), the air core coils of the primary tuning circuit and the air core coils of the secondary tuning circuit form the M coupling (an electromagnetic coupling).

An example of the related art is described in Japanese Unexamined Patent Application Publication No. 2003-110408

In the same manner as the television tuners mentioned above, the different receiving systems may be formed in accordance with the bands. However, there is a problem in that the circuit size increases since the number of components is large.

There is also a problem in that it is difficult to form the M coupled circuit for the low frequency band (VHF-Low) since the air core coils are used in the tuned circuit. Specifically, since it is difficult to secure a high degree of M coupling in the air core coil, it is difficult to form the M coupled circuit for all the bands.

### SUMMARY

According to a first aspect of the disclosure, a double tuned circuit includes: a primary tuning circuit connected to an input terminal; and a secondary tuning circuit connected to an output terminal. The primary tuning circuit has a primary capacitor connected between the input terminal and a ground and a primary inductor connected between the input terminal and the ground and formed of a first coupling line having a spiral shape. The secondary tuning circuit has a secondary capacitor connected between the output terminal and the ground and a secondary inductor connected between the output terminal and the ground and formed of a second coupling line having the same spiral shape as the first coupling line, arranged alternately with the first coupling line, and having an M-coupling with the first coupling line. A length of the first coupling line in the range from a connection point between the first coupling line and the input terminal to a ground point and a length of the second coupling line in the range from a connection point between the second coupling line and the output terminal to the ground point can be changed by a tuning frequency, and the lengths of those are substantially equal to each other.

With such a configuration, the first and second coupling lines are alternately arranged in the same spiral shape so as to form the M coupling. Therefore, it is possible to achieve a high degree of M coupling. As a result, it is possible to form the M coupled circuit for VHF-Low band of low frequency. Accordingly, by changing the length of the first coupling line in the range from the connection point between the first coupling line and the input terminal to the ground point and the length of the second coupling line in the range from the connection point between the second coupling line and the output terminal to the ground point, it is possible to change the tuning frequency. Thus, it enables selection of the bands including the VHF-Low band of low frequency by using one double tuned circuit. In addition, it is possible to receive all the bands of VHF-Low, VHF-Hi, and UHF by using one receiving system. As a result, it is possible to decrease the circuit size while achieving a reduction in cost.

According to a second aspect of the invention, a tuned circuit includes: an impedance matching inductor connected between an input terminal and a ground, formed of a first coupling line having a spiral shape, and matching an input impedance with an output impedance; a capacitor connected between an output terminal and the ground; and a tuning inductor connected between the output terminal and the ground and formed of a second coupling line having the same spiral shape as the first coupling line, arranged alternately with the first coupling line, and having an M-coupling with the first coupling line. A length of the first coupling line in the range from a connection point between the first coupling line and the input terminal to a ground point and a length of the second coupling line in the range from a connection point between the second coupling line and the output terminal to the ground point can be changed by a tuning frequency, and the lengths of those are substantially equal to each other.

With such a configuration, the first and second coupling lines are alternately arranged in the same spiral shape so as to form the M coupling. Therefore, it is possible to achieve a high degree of M coupling. As a result, it is possible to form the M coupled circuit for VHF-Low band of low frequency.

### BRIEF DESCRIPTION OF THE DRAWINGS

FIG. 1 is a block diagram illustrating a schematic configuration of a television tuner according to an embodiment of the invention.

FIG. 2 is a circuit diagram illustrating a specific configuration of a tuned circuit and a double tuned circuit of the television tuner of FIG. 1.

FIG. 3 is a top plan view illustrating an inductor included in the tuned circuit and the double tuned circuit of the television tuner of FIG. 1.

FIG. 4 is a perspective view illustrating a concrete example of the inductor included in the tuned circuit and the double tuned circuit of the television tuner of FIG. 1.

FIG. 5 is a block diagram illustrating a schematic configuration of an existing television tuner.

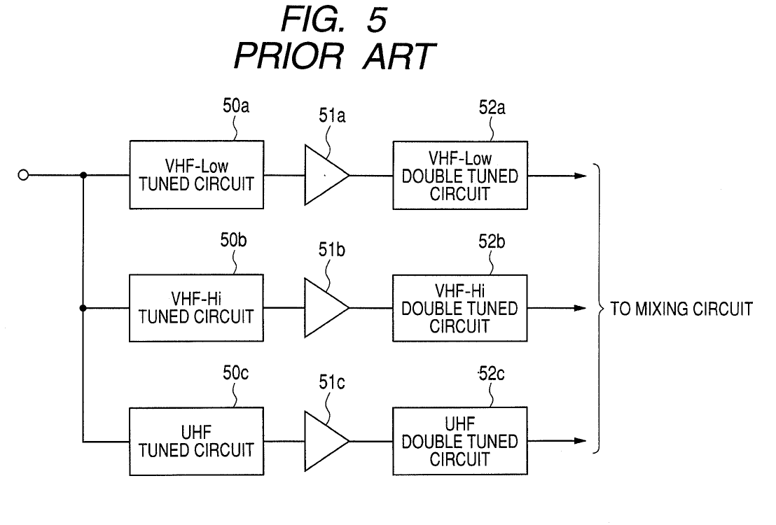

FIG. 6 a circuit diagram illustrating a specific configuration of a tuned circuit and a double tuned circuit of the television tuner of FIG. 5.

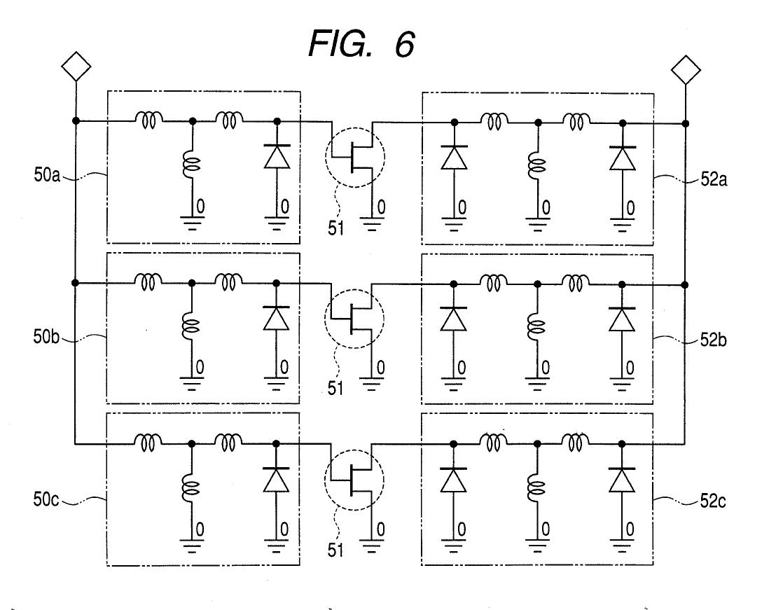

### DESCRIPTION OF EXEMPLARY EMBODIMENTS

Hereinafter, an embodiment of the invention will be described with reference to the accompanying drawings.

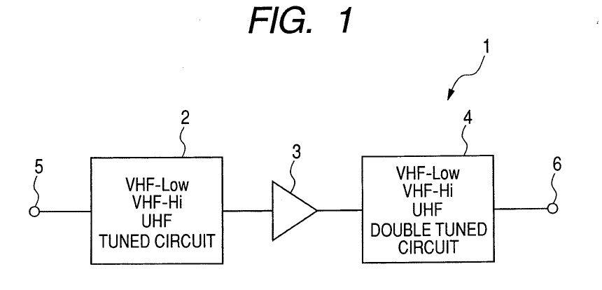

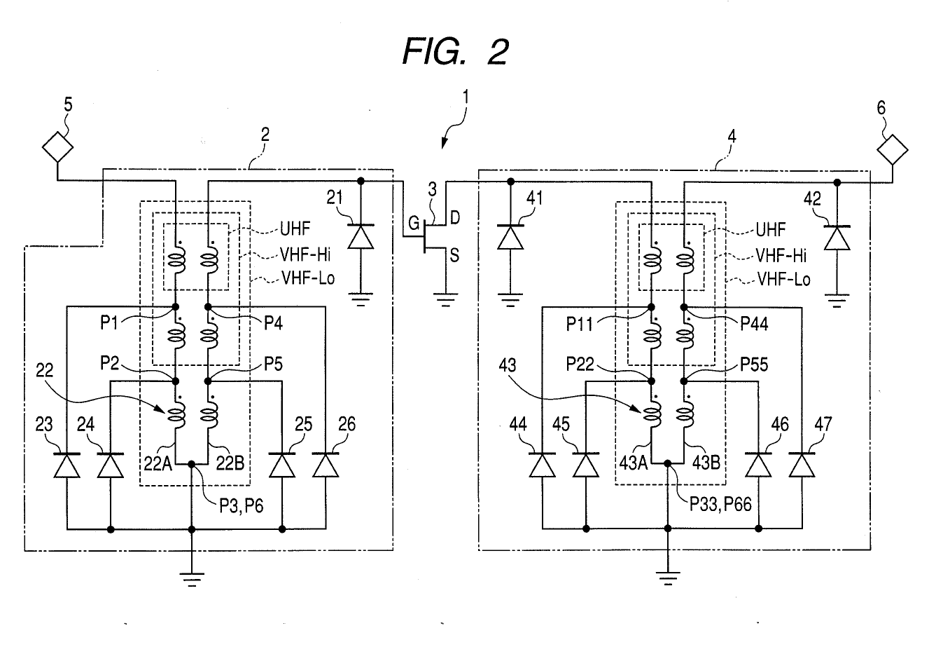

FIG. 1 is a schematic block diagram of a television tuner according to an embodiment of the invention. FIG. 2 is a circuit diagram of a tuned circuit and a double tuned circuit of the television tuner of FIG. 1. The television tuner 1 according to the embodiment includes a tuned circuit 2, an FET 3, and a double tuned circuit 4. The tuned circuit 2 has a spiral coil built therein as an inductor, and can be tuned to the bands of VHF-Low, VHF-Hi, and UHF. The FET 3 has a frequency characteristic capable of supporting the bands of VHF-Low, VHF-Hi, and UHF. The double tuned circuit 4 has a spiral coil built therein as an inductor, and can be tuned to the bands of VHF-Low, VHF-Hi, and UHF. An input terminal 5 of the tuned circuit 2 is connected to a low noise amp of the antenna side. An output terminal 6 of the double tuned circuit 4 is connected to a mixer.

The tuned circuit 2 includes a variable capacity diode 21, an inductor 22, and switching diodes 23 to 26 for high frequency switching formed of PIN diodes. The variable capacity diode 21 is provided between the output side of the tuned circuit 2 and the ground. In this case, the cathode of the variable capacity diode 21 is connected to the output side of the tuned circuit 2, and the anode thereof is connected to the ground.

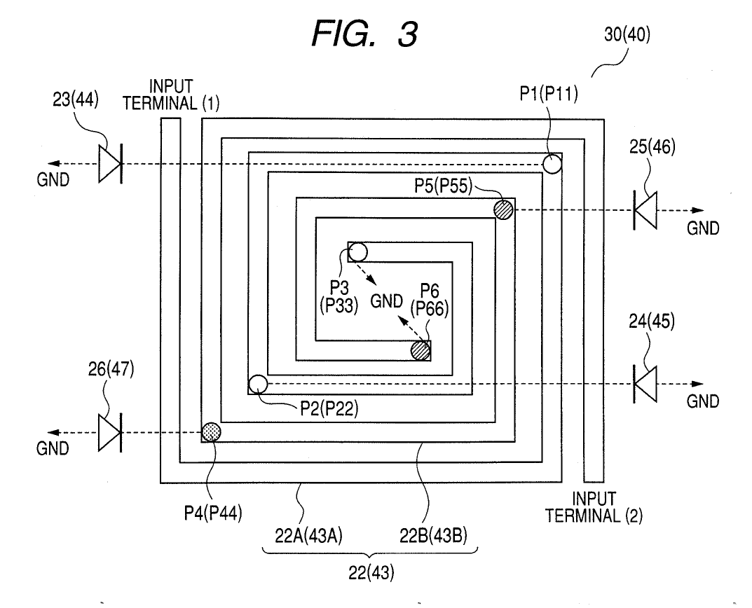

FIG. 3 is a top plan view illustrating pattern arrangement of the inductor 22. As shown in FIG. 3, the inductor 22 includes two coupling lines 22A and 22B having substantially the same length. The coupling lines 22A and 22B are formed on a wiring substrate 30 in spiral shapes separated by a predetermined distance. One outer end (an input terminal (1)) of the coupling line 22A constituting the inductor 22 is connected to the input terminal 5, and one outer end (an input terminal (2)) of the coupling line 22B is connected to the output side (the FET 3 side) of the tuned circuit 2. Further, the other ends which are two inner ends of the coupling lines 22A and 22B are connected to the ground.

The switching diodes 23 to 26 are for switching the bands of VHF-Low, VHF-Hi, and UHF by changing a physical length of the inductor 22. The diodes are connected between the ground and the predetermined positions of the two coupling lines 22A and 22B of the inductor 22. In the coupling line 22A, the point P1 is connected to the ground by the switching diode 23, the point P2 is connected to the ground by the switching diode 24, and the point P3, which is the inner end of the coupling line 22A, is constantly grounded. In the coupling line 22B, the point P4 is connected to the ground by the switching diode 26, the point P5 is connected to the ground by the switching diode 25, and the point P6, which is the inner end of the coupling line 22B, is constantly grounded.

The switching diode 26 is connected to a position at which the coupling line 22B is tuned to UHF together with the variable capacity diode 21. The switching diode 23 is connected to a position at which the impedance is matched by the switching diode 26 when the coupling line 22B is grounded at P1. The switching diode 25 is connected to a position at which the coupling line 22B is tuned to VHF-Hi together with the variable capacity diode 21. The switching diode 24 is connected to a position at which the impedance is matched by the switching diode 25 when the coupling line 22B is grounded at P5. The physical length of the coupling line 22B itself is set to a length suitable to the tuning of the VHF-Low frequency. As described above, the physical length of the inductor 22 is changed by turning on and off the switching diodes 23 to 26, and thereby the circuit is tuned to the bands of VHF-Low, VHF-Hi, and UHF. Furthermore, a PIN (P-Intrinsic-N) diode is suitable for the switching diodes 23 to 26 since it has a small resistance Rs when turned on and has a small capacity between the terminals when turned off.

The switching diodes 23 to 26 are on/off-controlled synchronously. In the case of VHF-Low reception, all the switching diodes 23 to 26 are controlled to be turned off. In the case of VHF-Hi reception, the switching diodes 24 and 25 are controlled to be turned on with the switching diodes 23 and 26 turned off. In the case of the UHF reception, the switching diodes 23 and 26 are controlled to be turned on.

In contrast, the double tuned circuit 4 includes a primary variable capacity diode 41, a secondary variable capacity diode 42, a primary inductor 43A, a secondary inductor 43B, and switching diodes 44 to 47. The primary inductor 43A and the variable capacity diode 41 provided between the ground and the input side of the double tuned circuit 4 constitutes a primary tuning circuit. The secondary inductor 43B and the variable capacity diode 42 provided between the ground and the output side of the double tuned circuit 4 constitutes a secondary tuning circuit.

The inductor 43 is configured in the same manner as the inductor 22 of the above-mentioned tuned circuit 2. As shown in FIG. 3, the inductor 43 includes two coupling lines 43A and 43B having substantially the same length. The coupling lines 43A and 43B are formed on a wiring substrate 40 in spiral shapes. One end (an input terminal (1)) of the coupling line 43A constituting the inductor 43 is connected to the input side of the double tuned circuit 4, and one end (an input terminal (2)) of the coupling line 43B is connected to the output side of the double tuned circuit 4. Further, the other ends which are two inner ends of the coupling lines 43A and 43B are connected to the ground.

The switching diodes 44 to 47 are connected between the ground and the predetermined positions P11, P22, P44, and P55 of the two coupling lines 43A and 43B of the inductor 43. The switching diodes 44 to 47 switch the bands of VHF-Low, VHF-Hi, and UHF by changing a physical length of the inductor 43. In the coupling line 43A, the point P11 is connected to the ground by the switching diode 44, the point P22 is connected to the ground by the switching diode 45, and the point P33, which is the inner end of the coupling line 43A, is constantly grounded. In the coupling line 43B, the point P44 is connected to the ground by the switching diode 47, the point P55 is connected to the ground by the switching diode 46, and the point P66, which is the inner end of the coupling line 43B, is constantly grounded.

The switching diode 44 of the primary tuning circuit is connected to a position (P11) at which the coupling line 43A is tuned to UHF together with the variable capacity diode 41. The switching diode 47 of the secondary tuning circuit is connected to a position (P44) at which the coupling line 43B is tuned to UHF together with the variable capacity diode 42. The switching diode 45 of the primary tuning circuit is connected to a position (P22) at which the coupling line 43A is tuned to VHF-Hi together with the variable capacity diode 41. The switching diode 46 of the secondary tuning circuit is connected to a position (P55) at which the coupling line 43B is tuned to VHF-Hi together with the variable capacity diode 42. The physical length of the inductor 43 is set to a length suitable to the tuning of the VHF-Low frequency.

As described above, the physical length of the inductor 43 is changed by turning on and off the switching diodes 44 to 47, and thereby the circuit is tuned to the bands of VHF-Low, VHF-Hi, and UHF. Furthermore, it is preferred that the switching diodes 44 to 47 have a small resistance Rs when turned on and has a small capacity between the terminals when turned off.

The switching diodes 44 to 47 are on/off-controlled synchronously. In the case of VHF-Low reception, all the switching diodes 44 to 47 are controlled to be turned off. In the case of VHF-Hi reception, the switching diodes 45 and 46 are controlled to be turned on with the switching diodes 44 and 47 turned off. In the case of the UHF reception, the switching diodes 44 and 47 are controlled to be turned on.

In the FET 3, the gate thereof is connected to the output terminal of the tuned circuit 2, the drain thereof is connected to the input terminal of the double tuned circuit 4, and the source thereof is grounded. The FET 3 has frequency characteristics capable of supporting all the bands of VHF-Low, VHF-Hi, and UHF.

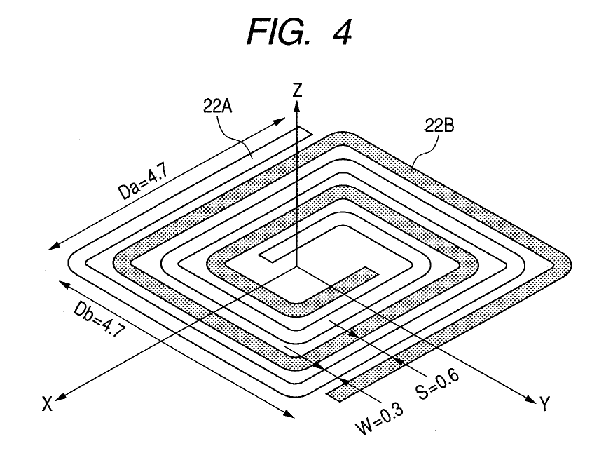

As described above, in the tuned circuit 2 and double tuned circuit 4, the inductor 22 (43) is formed of two coupling lines 22A (43A) and 22B (43B) alternately arranged in the spiral shape. By adopting such a configuration, it is possible to achieve a high degree of M coupling, compared with the inductor using the air core coils. As a result, it is possible to form the M coupled circuit even for VHF-Low band of low frequency. For example, the inductor 22 is formed on the basis of the sizes shown in FIG. 4. For example, the size Da of the inductor 22 in the X direction may be set to 4.7 mm, the size Db of the inductor 22 in the Y direction may be set to 4.7 mm, the line widths W of coupling lines 22A and 22B may be set to 0.3 mm, and the line spaces S of the coupling lines 22A and 22B may be set to 0.6 mm. In this case, each of inductances L1 and L2 of the coupling lines 22A and 22B is 20.52 (nH), and a coupling coefficient M is 12.54 (nH). The coupling coefficient M is several times higher than a coupling coefficient M of the general air core coil. As a result, it is also possible to achieve a similar high degree of M coupling between the coupling lines 43A and 43B even in the double tuned circuit 4.

As described above, since it is possible to obtain a high degree of M coupling between the coupling lines, the M coupled circuit is applicable to all the bands of VHF-Low, VHF-Hi, and UHF. As shown in FIG. 3, the inductor 22 (43) is formed of the two coupling lines 22A (43A) and 22B (43B) alternately arranged in the spiral shape, and the switching diodes 23 to 26 and the switching diodes 44 to 47 change the lengths of the coils. By using the tuned circuit 2 and the double tuned circuit 4 in which the inductor and the switching diodes are combined, it is possible to perform reception by switching all the bands of VHF-Low, VHF-Hi, and UHF.

The television tuner 1 configured as described above receives an input of a television broadcast signal at the input terminal 5, and outputs the television broadcast signal of the selected channel from the output terminal 6. The television broadcast signal is input to a mixing circuit not shown. At the time of the reception of UHF, the switching diodes 23 and 26 and the switching diodes 44 and 47 are turned on. In the tuned circuit 2, the coupling line 22A is grounded at P1 and the coupling line 22B is grounded at P4. Then, the tuned circuit 2 is tuned to the UHF band, thereby extracting the UHF signal. The UHF signal extracted by the tuned circuit 2 is applied to the gate of the FET 3, and the UHF signal is amplified and is introduced to the primary tuning circuit of the double tuned circuit 4. In the primary tuning circuit of the double tuned circuit 4, the coupling line 43A is grounded at P11. In the secondary tuning circuit thereof, the coupling line 43B is grounded at P44. By using the primary and secondary tuning circuits, the double tuned circuit 4 is tuned to the UHF band, thereby extracting the UHF signal.

At the time of the reception of VHF-Hi, the switching diodes 23 and 26 and the switching diodes 44 and 47 are turned off, and the switching diodes 24 and 25 and the switching diodes 45 and 46 are turned on. In the tuned circuit 2, the coupling line 22A is grounded at P2, and the coupling line 22B is grounded at P5. Then, the tuned circuit 2 is tuned to the VHF-Hi band, thereby extracting the VHF-Hi signal. The VHF-Hi signal extracted by the tuned circuit 2 is applied to the gate of the FET 3, and the VHF-Hi signal is amplified and is introduced to the primary tuning circuit of the double tuned circuit 4. In the primary tuning circuit of the double tuned circuit 4, the coupling line 43A is grounded at P22. In the secondary tuning circuit thereof, the coupling line 43B is grounded at P55. By using the primary and secondary tuning circuits, the double tuned circuit 4 is tuned to the VHF-Hi band, thereby extracting the VHF-Hi signal.

At the time of the reception of VHF-Low, all the switching diodes 23 to 26 and the switching diodes 44 to 47 are turned off. In the tuned circuit 2, the coupling line 22A is grounded at P3, and the coupling line 22B is grounded at P6. Then, the tuned circuit 2 is tuned to the VHF-Low band, thereby extracting the VHF-Low signal. The VHF-Low signal extracted by the tuned circuit 2 is applied to the gate of the FET 3, and the VHF-Low signal is amplified and is introduced to the primary tuning circuit of the double tuned circuit 4. In the primary tuning circuit of the double tuned circuit 4, the coupling line 43A is grounded at P33. In the secondary tuning circuit thereof, the coupling line 43B is grounded at P66. By using the primary and secondary tuning circuits, the double tuned circuit 4 is tuned to the VHF-Low band, thereby extracting the VHF-Low signal.

In the television tuner 1 according to the embodiment as described above, the switching diodes 23 to 26 of the tuned circuit 2 and the switching diodes 44 to 47 of the double tuned circuit 4 are on/off-controlled. Thereby, in each of the inductor 22 and 43, the lengths between the ground and the input terminal and between the ground and the output terminal of the two coupling lines are changed. As a result, it is possible to switch the bands of VHF-Low, VHF-Hi, and UHF. In addition, the tuned circuit 2 and the double tuned circuit 4 are configured so that each of the inductors 22 and 43 is formed of the two coupling lines arranged in the spiral pattern. Therefore, it is possible to support all the bands of VHF-Low, VHF-Hi, and UHF by using the M coupled circuit. As a result, it is possible to decrease the circuit size while achieving a reduction in cost.

Since each of the inductors 22 and 43 is formed of the two coupling lines wound in the spiral shapes, it is possible to obtain the high degree of M coupling. As a result, it is possible to form the M coupled circuit for VHF-Low band of low frequency. Furthermore, since it is difficult to obtain a degree of M coupling sufficient for VHF-Low by using the air core coil, it is difficult to form the M coupled circuit. Accordingly, by using a chip inductor for VHF-Low in the existing television tuner, the L coupled circuit is embodied.

Since the tuned circuit 2 and double tuned circuit 4 supports all the bands of VHF-Low, VHF-Hi, and UHF, it is possible to form the receiving system as one system by using one FET 3. As a result, it is possible to greatly reduce the cost thereof, compared with the case where receiving systems of the tuned circuit, the FET, and the double tuned circuit are formed individually for every band.

In the tuned circuit 2 according to the embodiment, the switching diodes 23 to 26 are connected between the ground and the predetermined positions of the two coupling lines 22A and 22B. However, the switching diodes 23 to 26 may be connected between predetermined positions on the input side and output side and the predetermined positions of the two coupling lines 22A and 22B. Likewise, in the double tuned circuit 4, the switching diodes 44 to 47 are connected between the ground and the predetermined positions of the two coupling lines 43A and 43B. However, the switching diodes 44 to 47 may be connected between predetermined positions on the input side and output side and the predetermined positions of the two coupling lines 43A and 43B.

The embodiments of the invention can be applicable to the tuned circuit and the double tuned circuit of the television tuner.

It should be understood by those skilled in the art that various modifications, combinations, sub-combinations and alterations may occur depending on design requirements and other factors insofar as they are within the scope of the appended claims of the equivalents thereof.

What is claimed is:

1. A double tuned circuit comprising:
a primary tuning circuit connected to an input terminal; and
a secondary tuning circuit connected to an output terminal,
wherein the primary tuning circuit has a primary capacitor connected between the input terminal and a ground and a primary inductor connected between the input terminal and the ground and formed of a first coupling line having a spiral shape,
wherein the secondary tuning circuit has a secondary capacitor connected between the output terminal and the ground and a secondary inductor connected between the output terminal and the ground and formed of a second coupling line having the same spiral shape as the first coupling line, arranged alternately with the first coupling line, and having an M-coupling with the first coupling line, and
wherein a length of the first coupling line in the range from a connection point between the first coupling line and the input terminal to a ground point and a length of the second coupling line in the range from a connection point between the second coupling line and the output terminal to the ground point can be changed by a tuning frequency, and the lengths of those are substantially equal to each other.

2. The double tuned circuit according to claim 1, further comprising:
a first switching element connected between the ground and a changeover position of the length of the first coupling line; and
a second switching element connected between the ground and a changeover position of the length of the second coupling line.

3. The double tuned circuit according to claim 1, further comprising:
a first switching element connected between the input terminal and a changeover position of the length of the first coupling line; and
a second switching element connected between the output terminal and a changeover position of the length of the second coupling line.

4. The double tuned circuit according to claim 1, wherein the capacitors are variable capacitors.

5. The double tuned circuit according to claim 1, wherein a television broadcast signal is input to the input terminal.

6. A tuned circuit comprising:
an impedance matching inductor connected between an input terminal and a ground, formed of a first coupling line having a spiral shape, and matching an input impedance with an output impedance;
a capacitor connected between an output terminal and the ground; and
a tuning inductor connected between the output terminal and the ground and formed of a second coupling line having the same spiral shape as the first coupling line, arranged alternately with the first coupling line, and having an M-coupling with the first coupling line,
wherein a length of the first coupling line in the range from a connection point between the first coupling line and the input terminal to a ground point and a length of the second coupling line in the range from a connection point between the second coupling line and the output terminal to the ground point can be changed by a tuning frequency, and the lengths of those are substantially equal to each other.
